(19) United States
(12) Patent Application Publication
(10) Pub. No.: US 2026/0280554 A1
(43) Pub. Date: Sep. 17, 2026

(54) SEMI-DISTRIBUTED DRIVER

(71) Applicant: MACOM Technology Solutions Holdings, Inc., Lowell, MA (US)

(72) Inventors: Anil Kumar, Lowell, MA (US); Atul Krishna Gupta, Lowell, MA (US); Rajiv Shukla, Lowell, MA (US)

(21) Appl. No.: 19/076,806

(22) Filed: Mar. 11, 2025

(51) Int. Cl. H03K 17/56

(52) U.S. Cl. CPC H03K 17/56

(57) ABSTRACT

Circuits, semiconductor devices, and systems are provided. An illustrative circuit includes a driver circuit having an unterminated input side comprising a plurality of input-side transistors, each of which are unterminated, where a first input-side transistor in the plurality of input-side transistors includes a gate that is connected to an input terminal and that is further connected to a second input-side transistor in the plurality of input-side transistors by a first transmission line. The driver circuit further includes a terminated output side including a plurality of output-side transistors, where a first output-side transistor in the plurality of output-side transistors comprises an emitter directly connected to a collector of the first input-side transistor, and where a collector of the first output-side transistor is connected to a second output-side transistor by a second transmission line.

### FIELD OF THE DISCLOSURE

The present disclosure is generally directed toward circuits and, in particular, toward driver circuits.

### BACKGROUND

High speed communication systems are being developed to improve performance with respect to data rates, power consumption, and size. The challenge is that improvements in one or more of these areas (e.g., increased data rates) may result in a tradeoff with respect to other areas (e.g., increased power consumption and/or size).

Driver circuits are used at the transmission side and/or receiving side of a communication system. At data rates greater than 200 Gbits/sec, the use of a lumped driver design becomes impractical. At these higher data rates, the use of a distributed driver design may be desired. While there is a desire to make the drivers operate at higher communication speeds, there is also a desire to minimize the footprint and cost of producing such devices.

### SUMMARY

Conventional distributed drivers employ both input and output termination, which causes the distributed driver to occupy a relatively large silicon footprint. While this design helps improve the performance of the driver (e.g., improve bandwidth, improve Signal to Noise Ratio (SNR), improve Output Return Loss (ORL), minimize ripples/reflections/parasitics, etc.), the input and output termination results in the driver circuit consuming a relatively large silicon footprint, thereby increasing the size of the driver and the component in which the driver is provided. In short, conventional distributed drivers exhibit a large silicon footprint and use matched transmission line for distribution on both input and output sides of the circuit.

Embodiments of the present disclosure contemplate a distributed driver without an input-side termination. According to at least some embodiments, allowing the input side of the driver circuit to remain unterminated may result in higher gains for the same amount of power consumption. Furthermore, the distributed driver designs contemplated herein may also allow for a dissimilar type and/or length of transmission lines used for distribution on the input side as compared to the output side, thereby providing enhanced design flexibility. Yet another possible advantage is that the proposed distributed driver design enables a reduction of parasitics on the emitter and/or collector side of the input device, thereby enhancing bandwidth.

According to at least some embodiments, while the input side of the driver circuit may be unterminated, the output side of the driver circuit may still be terminated in the normal fashion. Such a design can allow the output side distribution to be optimized for ORL while the input side of the driver circuit may be optimized for some other aspect of the driver performance (e.g., power consumption, emitter degeneration, footprint, etc.). Embodiments of the present disclosure contemplate the use of a high impedance transmission line as a distributed inductance at the output to enhance the ORL performance. Meanwhile, the layout area (e.g., footprint) of the driver circuit can be greatly reduced in comparison to conventional distributed drivers because the input side is left unterminated. This may result in the ability to maintain the bandwidth enhancement advantage of the distributed driver design without having to tradeoff for a larger footprint.

In some embodiments, a driver circuit is provided that includes: an unterminated input side comprising a plurality of input-side transistors, each of which are unterminated, where a first input-side transistor in the plurality of input-side transistors comprises a gate that is connected to an input terminal and that is further connected to a second input-side transistor in the plurality of input-side transistors by a first transmission line; and a terminated output side comprising a plurality of output-side transistors, where a first output-side transistor in the plurality of output-side transistors comprises an emitter directly connected to a collector of the first input-side transistor, and where a collector of the first output-side transistor is connected to a second output-side transistor by a second transmission line.

In some embodiments, a semiconductor device is provided that includes: a driver circuit, comprising; an unterminated input side comprising a plurality of input-side transistors, each of which are unterminated, where a first input-side transistor in the plurality of input-side transistors comprises a gate that is connected to an input terminal and that is further connected to a second input-side transistor in the plurality of input-side transistors by a first transmission line; and a terminated output side comprising a plurality of output-side transistors, where a first output-side transistor in the plurality of output-side transistors comprises an emitter directly connected to a collector of the first input-side transistor, and where a collector of the first output-side transistor is connected to a second output-side transistor by a second transmission line.

In some embodiments, a system is provided that includes: a plurality of driver stages, wherein each of the plurality of driver stages comprises a pair of input-side transistors and a pair of output-side transistors, wherein the input-side transistors in the pair of input-side transistors are left unterminated, wherein the output-side transistors in the pair of output-side transistors are terminated, wherein at least two driver stages in the plurality of driver stages comprise an input-side transmission line connecting respective input-side transistors as well as an output-side transmission line connecting respective output-side transistors, and wherein a delay introduced by the input-side transmission line is different from a delay introduced by the output-side transmission line.

According to at least some aspects, the unterminated input side may have an impedance that is different from an impedance of the terminated output side.

According to at least some aspects, a delay introduced by the first transmission line is substantially less than one Unit Interval (UI), which corresponds to a symbol rate for the driver circuit. In one example, the delay is less than or equal to 20 picoseconds. In one example, the delay introduced by the second transmission line is different from the delay introduced by the first transmission line.

According to at least some aspects, the first input-side transistor and the first output-side transistor are part of a first stage comprising a pair of input-side transistors and a pair of output-side transistors, where the pair of input-side transistors are coupled to one another by a capacitor and one or more resistors, where each output-side transistor in the pair of output-side transistors is connected directly to a respective input-side transistor in the pair of input-side transistors. In one example, the unterminated input side includes a first input terminal connected to one input-side transistor in the pair of input-side transistors as well as a second input terminal connected to another input-side transistor in the pair of input-side transistors. In one example, the terminated output side comprises a first output terminal connected to one output-side transistor in the pair of output-side transistors as well as a second output terminal connected to another output-side transistor in the pair of output-side transistors.

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented later.

### BRIEF DESCRIPTION OF THE DRAWINGS

The present disclosure is described in conjunction with the appended figures, which are not necessarily drawn to scale:

FIG. 1 is a block diagram illustrating a communication system according to at least some embodiments of the present disclosure;

FIG. 2 illustrates details of a first driver circuit according to at least some embodiments of the present disclosure;

FIG. 3 illustrates details of a second driver circuit according to at least some embodiments of the present disclosure; and

FIG. 4 illustrates a method of configuring and operating a driver circuit according to at least some embodiments of the present disclosure.

### DETAILED DESCRIPTION

It is with respect to the above-noted challenges that embodiments of the present disclosure were contemplated. In particular, a system, circuits, and method of operating such circuits are provided that solve the drawbacks associated with existing driver circuits.

While embodiments of the present disclosure will primarily be described in connection with circuits used in high-bandwidth applications, it should be appreciated that embodiments of the present disclosure are not so limited. Furthermore, while embodiments of the present disclosure are contemplated for use in connection with high-speed communications over copper or fiber, it should be appreciated that the claims are not limited to high-speed electrical and optical or EO communications. Indeed, the driver circuit(s) depicted and described herein may be utilized in any number of applications utilizing an amplifier (e.g., transmitter applications, receiver applications, filtering applications, etc.). Example embodiments of the present disclosure will be described in connection with broadband applications, but it should be appreciated that the circuit(s) depicted and described herein can be utilized in other non-broadband applications.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB). For example, circuit components depicted and described herein may be provided on a single piece of silicon (e.g., a single semiconductor die), on multiple pieces of silicon, on a PCB, or combinations thereof.

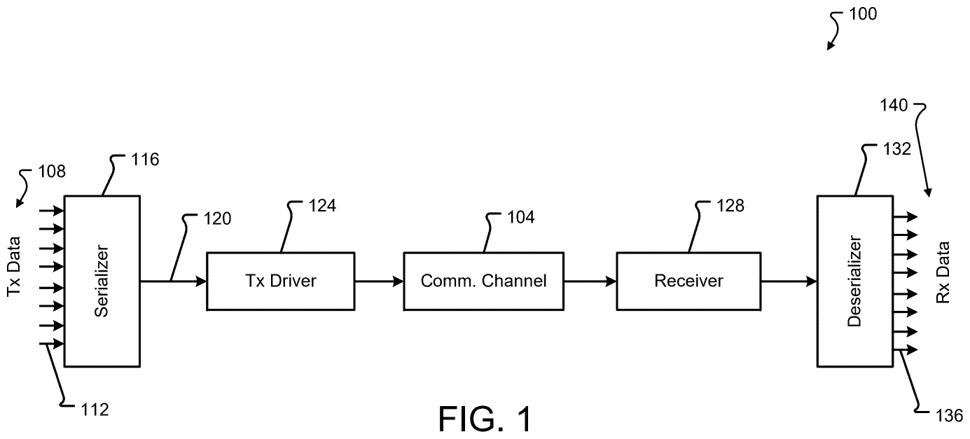

Referring initially to FIG. 1, an illustrative communication system 100 will be described in accordance with at least some embodiments of the present disclosure. The system 100 represents but one possible environment of use of the innovation(s) disclosed herein. As shown, data to be transmitted, referred to as transmit data 108 is provided over two or more parallel paths 112 to a serializer 116. The serializer 116 converts the data received from the two or more parallel paths 112 to a serial stream of data on serial data path 120. The serial stream of data is presented to a transmitter driver 124 which amplifies the signal to a level suitable for transmission over a communication channel 104.

The communication channel 104 may include or correspond to any suitable type of communication channel, such as a channel used for high-speed data transmission. The communication channel 104 may correspond to or include one or more optical fibers. The communication channel 104 may alternatively or additionally correspond to or include one or more electrically-conductive lines such as PCB traces, coaxial cables, connectors. Thus, the data transmitted by the transmitter driver 124 may include an optical signal and/or electrical signal. In one embodiment, the communication channel 104 is length of fiber, which may span in length from a few meters to tens of kilometers. However, the method and apparatus disclosed herein may be used for channels of any length or type, such as but not limited to, fiber channels, circuit board traces, coaxial cables, or wired channels, all of which may be any suitable length.

After passing through the communication channel 104, the data is presented to a receiver circuit 128. The receiver circuit 128 may include one or more gain stages. The transmitter driver 124 may include one or more drivers. The transmitter driver 124 and/or receiver circuit 128 may be provided with one or more amplifier circuits comprising one or more biasing circuits. The transmitter driver 124 and/or receiver circuit 128 may also include one or more equalizer circuits. The equalizer(s) may be configured to reduce the signal attenuating effects of the communication channel 104. The receiver 128 may also include one or more driver circuits as depicted and described herein.

After equalization, the data is provided to a deserializer 132 which converts the serial data stream to a parallel data path on the two or more data paths 136. The data output by the deserializer may be regarded as received data 140 that can be processed by a communication device that includes the receiver circuit 128 and deserializer 132.

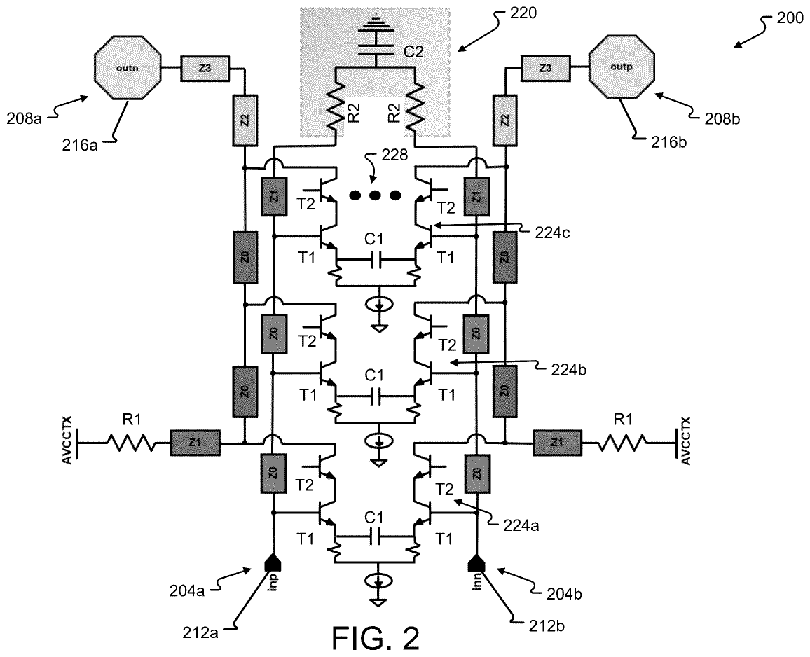

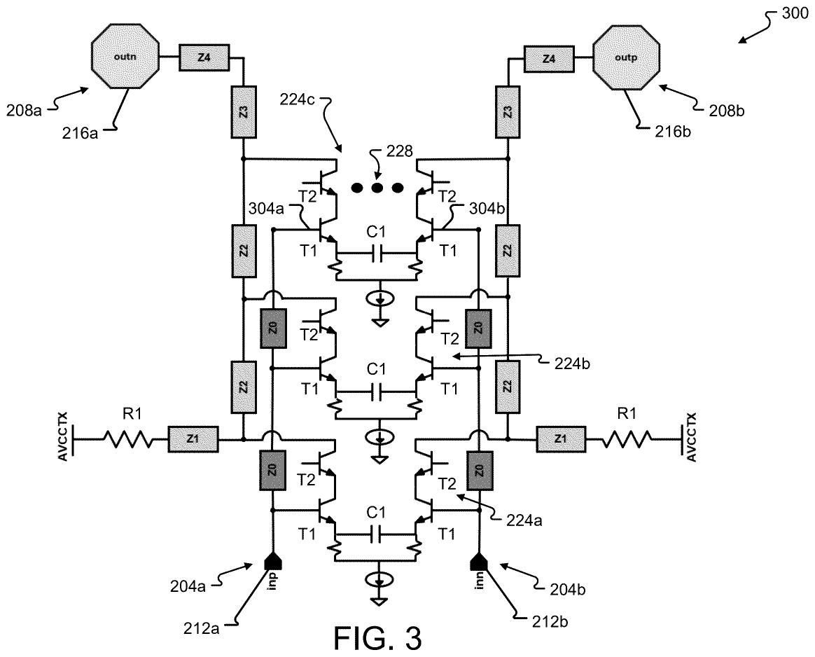

Referring now to FIGS. 2-3, various examples of circuit 200, 300 configurations that may be used in connection with a communication system 100 will be described in accordance with at least some embodiments of the present disclosure. As a non-limiting example, a circuit 200, 300 may be provided as part of the transmitter driver 124 that is used to amplify a signal prior to transmission of the signal on the communication channel 104. Alternatively or additionally, a circuit 200, 300 may be provided as part of a receiver 128.

FIG. 2 illustrates an example circuit 200. The circuit 200 may correspond to a distributed driver circuit in which both an input side 204a, 204b and an output side 208a, 208b are terminated. As described herein, the circuit 200 may have both its input side 204a, 204b and output side 208a, 208b terminated by way of connecting the sides to a terminating resistor.

The circuit 200 is illustrated as a distributed driver circuit in which input terminals 212a, 212b of the input side 204a, 204b are connected to input-side transistor(s) T1. While three pairs of input-side transistors T1 are illustrated in FIG. 2, it should be appreciated that the circuit 200 may include one, two, three, four, . . . , ten, or more input-side transistors T1 as illustrated by ellipses 228. In some embodiments, the first input side 204a may include a first input terminal 212a, which may also be referred to as a p-side input (e.g., inp). The second input side 204b may include a second input terminal 212a, which may also be referred to as an n-side input (e.g., inn). The input terminal 212a, 212b are connected to inputs (e.g., a base) of the input-side transistors T1. Each pair of input-side transistors T1 may have their emitters connected to one another through a capacitor C1 and a pair of resistors, which are grounded through a current source. The collectors of each input-side transistor T1 may be directly connected to an emitter of an output-side transistor T2.

Pairs of input-side transistors T1 may be combined with pairs of output-side transistors T2 into corresponding driver stages 224a, 224b, 224c. While circuit 200 is shown to include three driver stages 224a, 224b, 224c, it should be appreciated that the circuit 200 may include greater or fewer stages. For example, the circuit 200 may include one, two, three, four, . . . , ten, or more stages without departing from the scope of the present disclosure. As noted above, each stage 224a, 224b, 224c may include a capacitor C1 and a pair of resistors connected between the emitters of the input-side transistors T1 and ground through a current source. The size and type of transistors used for the input-side transistors T1 and/or the output-side transistors T2 may depend upon the environment in which the circuit 200 is deployed and the data rate desired for the circuit 200.

In some embodiments, a pair of input-side transistors T1 in one stage (e.g., a first stage 224a) may be connected to a pair of input-side transistors T1 in a next stage (e.g., a second stage 224b) by a transmission line Z0. As further shown in FIG. 2, the pair of input-side transistors T1 in the second stage 224b may be connected to a pair of input-side transistors T1 in a next stage (e.g., a third stage 224c) by another transmission line Z0. The length/impedance of one transmission line Z0 connecting one input-side transistor T1 to another input-side transistor T1 does not necessarily need to be the same as another transmission line Z0, but it may be possible for multiple transmission lines Z0 on the input side 204a, 204b to have the same length/impedance.

The input-side transistors T1 of the final stage (e.g., third stage 224c in FIG. 2) are shown to be terminated to ground via a termination subcircuit 220. The length/impedance of the transmission line Z1 into the termination subcircuit 220 may be the same or different from the length/impedance of the transmission lines Z0 between stages. The termination subcircuit 220 is shown to include a pair of input-side termination resistors R2 and an input-side termination capacitor C2 that provides a pathway to ground for the input side 204a, 204b. The termination subcircuit 220 may help to minimize reflections from the input side 204a, 204b into other portions of the circuit 200 (e.g., the output side 208a, 208b). While the termination subcircuit 220 may help to improve certain performance aspects of circuit 200, the termination subcircuit 220 may also increase the silicon footprint of the circuit 200 and/or increase the power consumption of the circuit 200.

Furthermore, use of the termination subcircuit 220 may require a matched transmission line distribution between the input side 204a, 204b (e.g., bases of input-side transistors T1) and the output side 208a, 208b (e.g., collectors of the output-side transistors T2). As can be seen in FIG. 2, the output-side transistors T2 in the first stage 224a have their collectors terminated through transmission lines Z1. Each output side 208a, 208b is shown to be terminated through an output-side termination resistor R1 to a control voltage AVCCTX.

FIG. 2 further illustrates that output-side transistors T2 of each stage (e.g., the first stage 224a) may be connected to a pair of output-side transistors T2 of a next stage (e.g., the second stage 224b) by a transmission line Z0. The length/impedance of the transmission line Z0 connecting output-side transistors T2 may be the same or similar to the length/impedance of the transmission lines Z0 connecting input-side transistors T1. The output-side transistors T2 of the last stage (e.g., third stage 224c) may have their collectors connected to an output terminal 216a, 216b by one or more transmission lines Z2, Z3. The length/impedance of the transmission lines Z2 and/or Z3 may be the same as or different from the length/impedance of the transmission lines Z0 connecting the other output-side transistors T2. In some embodiments, the length/impedance of the transmission lines Z0 are greater than the length/impedance of other transmission lines (e.g., transmission lines Z1, Z2, Z3) in the circuit 200. In some embodiments, the length/impedance of the transmission lines Z0 are greater than the length/impedance of the transmission lines Z1. Furthermore, as a non-limiting example, the length/impedance of the transmission lines Z1 may be greater than the length/impedance of the transmission lines Z2. Similarly, as a non-limiting example, the length/impedance of the transmission lines Z2 may be greater than the length/impedance of the transmission lines Z3, meaning that transmission lines Z3 have the shortest length in circuit 200. As can be appreciated, the circuit 200 may be configured to accept an input signal at the input terminals 212a, 212b and then produce an appropriate or corresponding output signal at the output terminals 216a, 216b, which can be used to drive another device in the system 100, such as a laser, diode, optoelectronic transceiver, etc.

FIG. 3 illustrates another circuit 300 in which the termination subcircuit 220 is removed. In other words, base terminals 304a, 304b of the input-side transistors T1 in the final stage (e.g., the third stage 224c) are left unterminated. Leaving the base terminals 304a, 304b unterminated may provide a number of surprising impacts on the performance of circuit 300 relative to circuit 200. For instance, leaving the input side 204a, 204b unterminated may result in reflections from the input side 204a, 204b being produced.

It may appear that the failure to absorb reflections (e.g., by removal of the termination subcircuit 220) would be troublesome for the performance of circuit 300, but the reflection issues can be overcome if the circuit 300 is designed appropriately. In accordance with at least some embodiments, the circuit 300 is designed with shorter transmission lines between output-side transistors T2 on the output side 208a, 208b of circuit 300. In other words, the circuit 300 is designed in such a way that delays on the input side 204a, 204b are allowed to be different from (e.g., not match) delays on the output side 208a, 208b. Delay differences between the input side 204a, 204b and the output side 208a, 208b are achieved by using transmission lines of different length/impedance on the input side 204a, 204b as compared to the output side 208a, 208b, which is indicated by the input side 204a, 204b having transmission lines Z0 whereas the output side 208a, 208b utilizes transmission lines Z1, Z2, Z3, and/or Z4.

Providing circuit 300 with unmatched input side 204a, 204b and output side 208a, 208b while also shortening the length of each transmission line on the output side 208a, 208b helps to reduce the overall footprint of circuit 300 as compared to circuit 200 in addition to reducing the power consumption of the circuit 300 as compared to circuit 200. As noted above, leaving the input side 204a, 204b unterminated may result in reflections from the input side 204a, 204b re-entering the circuit 300. The reflections can be overcome by utilizing transmission lines of relatively short length in circuit 300.

In accordance with at least some embodiments, the transmission lines Z0, Z1, Z2, Z3, and/or Z4 can be selected to have a length that is substantially less than one Unit Interval (UI), in terms of delay, which corresponds to the symbol rate for which the circuit 300 is designed. Providing transmission lines with a length that is substantially less than or equal to one UI refers to a length of transmission line that is small enough, in terms of delay, to not create a reflection that impacts a performance of the circuit 300. In some embodiments, the circuit 300 may exhibit a delay at each transmission line between 0.2 picoseconds and 20 picoseconds. If the circuit 300 is designed to operate at a symbol rate greater than or equal to 20 picoseconds, then the delay at any transmission line will be less than the UI. If the delay through each transmission line is less than one UI (e.g., the delay introduced by any transmission line is substantially less than the UI for the circuit 300), then the impacts of the reflections produced by the unterminated input side 204a, 204b are minimized and/or mitigated. In other words, by using a relatively short transmission line between each transistor (e.g., input-side transistors T1 and/or output-side transistors T2), the delay at any transmission line can be maintained below the UI for the circuit 300. Such a design can allow for the input side 204a, 204b to be left unterminated.

Moreover, leaving the input side 204a, 204b unterminated allows for a circuit 300 that does not require matching between the input side 204a, 204b and output-side 208a, 208b. In other words, when a decision is made to leave the input side 204a, 204b unterminated, it becomes possible to have additional design flexibility with the circuit 300. For example, leaving the input side 204a, 204b unterminated allows for the transmission lines Z0 on the input side 204a, 204b to have a different length/impedance as compared to any of the transmission lines Z1, Z2, Z3, and/or Z4 on the output side 208a, 208b. Particularly, because the impacts of the reflection from the input side 204a, 204b are negligible due to the use of shorter transmission lines and the removal of the termination subcircuit 220, it is no longer required to match impedances and/or delays between the input side 204a, 204b and output side 208a, 208b.

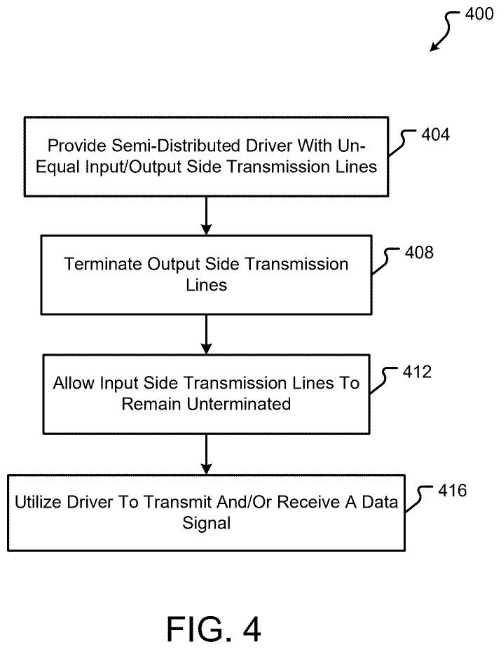

Referring now to FIG. 4, a method 400 will be described in accordance with at least some embodiments of the present disclosure. The method 400 begins by providing a driver circuit 300 with unequal or unmatched input sides and output sides (step 404). As a non-limiting example, the circuit 300 may be provided with an input side 204a, 204b having a first delay and/or first impedance and an output side 208a, 208b having a second delay and/or second impedance that is different from the first delay and/or first impedance, respectively. The differences between the delay and/or impedances of the input side 204a, 204b and output side 208a, 208b can be achieved by using transmission lines of different lengths on the input side 204a, 204b as compared to the output side 208a, 208b. In some embodiments, the transmission lines at least on the output side 208a, 208b introduce a delay that is less than a UI of the circuit 300, meaning that the transmission lines are relatively short.

The method 400 further includes terminating the output side 208a, 208b (step 408). In some embodiments, terminating the output side 208a, 208b may include connecting one or more nodes of the output side 208a, 208b to a control voltage and/or to ground.

The method 400 may further include allowing the input side 204a, 204b to remain unterminated (step 412). Allowing the input side 204a, 204b to remain unterminated may also be referred to as allowing the input-side transistors T1 to float by not connecting any terminal thereof to ac-ground, either directly or through one or more elements of a termination subcircuit 220.

The method 400 may continue by utilizing the circuit 300 to transmit and/or receiving a data signal in a communication system 100 (step 416). In some embodiments, the circuit 300 may be provided as a semi-distributed driver circuit and without an end termination at the input side 204a, 204b. The circuit 300 can be used as a driver circuit for a laser, diode, optoelectronic transceiver, or the like.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A driver circuit, comprising:
an unterminated input side comprising a plurality of input-side transistors, each of which are unterminated, wherein a first input-side transistor in the plurality of input-side transistors comprises a gate that is connected to an input terminal and that is further connected to a second input-side transistor in the plurality of input-side transistors by a first transmission line; and
a terminated output side comprising a plurality of output-side transistors, wherein a first output-side transistor in the plurality of output-side transistors comprises an emitter directly connected to a collector of the first input-side transistor, and wherein a collector of the first output-side transistor is connected to a second output-side transistor by a second transmission line.

2. The circuit of claim 1, wherein an impedance of the unterminated input side is different from an impedance of the terminated output side.

3. The circuit of claim 1, wherein a delay introduced by the first transmission line is less than one Unit Interval (UI), which corresponds to a symbol rate for the driver circuit.

4. The circuit of claim 3, wherein the delay is less than or equal to 20 picoseconds.

5. The circuit of claim 3, wherein a delay introduced by the second transmission line is less than one UI.

6. The circuit of claim 5, wherein the delay introduced by the second transmission line is different from the delay introduced by the first transmission line.

7. The circuit of claim 1, wherein the first input-side transistor and the first output-side transistor are part of a first stage comprising a pair of input-side transistors and a pair of output-side transistors, wherein the pair of input-side transistors are coupled to one another by a capacitor and one or more resistors, wherein each output-side transistor in the pair of output-side transistors is connected directly to a respective input-side transistor in the pair of input-side transistors.

8. The circuit of claim 7, wherein the unterminated input side comprises a first input terminal connected to one input-side transistor in the pair of input-side transistors as well as a second input terminal connected to another input-side transistor in the pair of input-side transistors.

9. The circuit of claim 7, wherein the terminated output side comprises a first output terminal connected to one output-side transistor in the pair of output-side transistors as well as a second output terminal connected to another output-side transistor in the pair of output-side transistors.

10. A semiconductor device, comprising:
a driver circuit, comprising;
an unterminated input side comprising a plurality of input-side transistors, each of which are unterminated, wherein a first input-side transistor in the plurality of input-side transistors comprises a gate that is connected to an input terminal and that is further connected to a second input-side transistor in the plurality of input-side transistors by a first transmission line; and
a terminated output side comprising a plurality of output-side transistors, wherein a first output-side transistor in the plurality of output-side transistors comprises an emitter directly connected to a collector of the first input-side transistor, and wherein a collector of the first output-side transistor is connected to a second output-side transistor by a second transmission line.

11. The semiconductor device of claim 10, wherein an impedance of the unterminated input side is different from an impedance of the terminated output side.

12. The semiconductor device of claim 10, wherein a length of the first transmission line is different from a length of the second transmission line.

13. The semiconductor device of claim 10, wherein a delay introduced by the first transmission line is substantially less than one Unit Interval (UI), which corresponds to a symbol rate for the driver circuit.

14. The semiconductor device of claim 13, wherein the delay is less than or equal to 20 picoseconds.

15. The semiconductor device of claim 13, wherein a delay introduced by the second transmission line is substantially less than one UI.

16. The semiconductor device of claim 15, wherein the delay introduced by the second transmission line is different from the delay introduced by the first transmission line.

17. The semiconductor device of claim 10, wherein the first input-side transistor and the first output-side transistor are part of a first stage comprising a pair of input-side transistors and a pair of output-side transistors, wherein the pair of input-side transistors are coupled to one another by a capacitor and one or more resistors, wherein each output-side transistor in the pair of output-side transistors is connected directly to a respective input-side transistor in the pair of input-side transistors.

18. The semiconductor device of claim 17, wherein the unterminated input side comprises a first input terminal connected to one input-side transistor in the pair of input-side transistors as well as a second input terminal connected to another input-side transistor in the pair of input-side transistors.

19. The semiconductor device of claim 17, wherein the terminated output side comprises a first output terminal connected to one output-side transistor in the pair of output-side transistors as well as a second output terminal connected to another output-side transistor in the pair of output-side transistors.

20. A system, comprising:
a plurality of driver stages, wherein each of the plurality of driver stages comprises a pair of input-side transistors and a pair of output-side transistors, wherein the input-side transistors in the pair of input-side transistors are left unterminated, wherein the output-side transistors in the pair of output-side transistors are terminated, wherein at least two driver stages in the plurality of driver stages comprise an input-side transmission line connecting respective input-side transistors as well as an output-side transmission line connecting respective output-side transistors, and wherein a delay introduced by the input-side transmission line is different from a delay introduced by the output-side transmission line.
